(19) United States
(12) Patent Application Publication
(10) Pub. No.: US 2008/0272449 A1
(43) Pub. Date: Nov. 6, 2008

(54) Solid-state image pickup device, solid-state image pickup device manufacturing method and camera

(76) Inventors: Yuichi Inaba, Osaka (JP); Masahiro Kasano, Osaka (JP)

Correspondence Address: MCDERMOTT WILL & EMERY LLP, 600 13TH STREET, NW, WASHINGTON, DC, 20005-3096, US

(21) Appl. No.: 11/665,601

(22) PCT Filed: Oct. 14, 2005
(86) PCT No.: PCT/JP2005/018976

§ 371 Date: Apr. 18, 2007

(30) Foreign Application Priority Data
Oct. 27, 2004 (JP) 2004-312927

(51) Int. Cl. H01L 31/00; H01L 21/00

(52) U.S. Cl. 257/432; 438/69; 257/E31.001; 257/E21.001

(57) ABSTRACT

A solid-state image pickup device 1 has a construction in which a P-type semiconductor layer 102, an insulating layer 104, a color filter 106, a light transmitting layer 107, and a light focusing layer 108 are sequentially laminated on an N-type semiconductor layer 101. A plurality of photodiodes 103 are formed in the P-type semiconductor layer 102 on the insulating layer 104 side. A light shielding film 105 is formed in the insulating layer 104. The plurality of photodiodes 103 are densely mounted by being unequally arranged two-dimensionally. The light-focusing efficiency can be improved because the plurality of photodiodes 103 closely arranged to each other share the light transmitting layer 107 and the light focusing layer 108.

### TECHNICAL FIELD

The present invention relates to a solid-state image pickup device, and especially relates to a technology for improving light-focusing efficiency of a solid-state image pickup device in which a plurality of light receiving elements are densely mounted.

### BACKGROUND ART

A solid-state image pickup device is composed of a plurality of light receiving elements arranged two-dimensionally. FIG. 1 is a plan view showing a schematic construction of a solid-state image pickup device of a conventional technology. As shown in FIG. 1, a solid-state image pickup device 7 includes light receiving elements 701, a vertical shift register 703, a horizontal shift register 702, and a drive circuit 704. The light receiving elements 701 are arranged at regular intervals in a grid.

When the vertical shift register 703 selects one row of light receiving elements 701, and the horizontal shift register 702 selects a row signal of the row, an image signal of a light receiving element 701 is outputted. The drive circuit 704 drives the vertical shift register 703 and the horizontal shift register 702. Note that the light receiving element 701 has an amplifier for amplifying a signal voltage generated by a photodiode, which is not illustrated.

FIG. 2 is a cross section showing a part of a construction of the solid-state image pickup device of the conventional technology. As shown in FIG. 2, the solid-state image pickup device 7 has a construction in which a P-type semiconductor layer 802, an insulating layer 804, and a color filter 806 are sequentially laminated on an N-type semiconductor layer 801. A photodiode 803 is formed in the P-type semiconductor layer 802 on the insulating layer 804 side. A light shielding film 805 is formed in the insulating layer 804. A microlens 807 is provided on the color filter 806.

The microlens 807 focuses incident light on the photodiode 803. The color filter 806 transmits only light having a particular wavelength in the incident light. The photodiode 803 generates a charge corresponding to a strength of light entering therein.

Patent Document 1: “Basis and application of a CCD/MOS image sensor”, CQ publishing company, written by Kazuya Yonemoto, pages 95-101.

### DISCLOSURE OF THE INVENTION

### Problems the Invention is Going to Solve

To realize a higher resolution for such a solid-state image pickup device, a higher number of pixels are necessary. Therefore, a high-density mounting of light receiving elements is required.

However, each of the light receiving elements includes a photoelectric conversion unit for converting incident light, an amplifying unit for amplifying an image signal obtained by the photoelectric conversion unit, a wiring unit for outputting the image signal, a transistor for switching on and off, and the like. Since it is difficult to downsize the photoelectric conversion unit and the amplifying unit, when densely mounting light receiving elements (equal to or larger than 200 million pixels, for example), photodiodes cannot be arranged at regular intervals. This makes the arrangement of the photodiodes unequal.

If photodiodes are densely arranged, the corresponding microlenses need to be downsized. As a result, enough light-gathering power cannot be obtained, which causes a decrease in a light receiving sensitivity of the solid-state image pickup device.

To solve the above-mentioned problem, the present invention aims to provide a solid-state image pickup device in which light receiving elements are densely mounted and which has high light-focusing efficiency, a manufacturing method of the solid-state image pickup device, and a camera using the solid-state image pickup device.

### Means of Solving the Problems

The above problem is solved by a solid-state image pickup device, comprising: a plurality of photoelectric conversion units arranged two-dimensionally; and a plurality of light focusing units that focus incident light on the plurality of photoelectric conversion units, wherein at least two photoelectric conversion units out of the plurality of photoelectric conversion units are located more closely to each other than other photoelectric conversion units, and the at least two photoelectric conversion units share one of the plurality of light focusing units.

### Effects of the Invention

With the above-stated construction, the at least two photoelectric conversion units that are located more closely to each other can share the light focusing unit, even if the plurality of photoelectric conversion units are unequally and densely arranged two-dimensionally. Therefore, the high light-focusing efficiency can be realized. Also, each of the plurality of light focusing units includes: a transmitting unit that transmits light entering therein; and a refracting unit that surrounds the transmitting unit, and refracts incident light toward each of the plurality of photoelectric conversion units.

Moreover, a refractive index of the transmitting unit is larger than a refractive index of the refracting unit. Furthermore, a refractive index of the refracting unit is lower in an area farther from the transmitting unit. With the above-stated construction, the light-focusing efficiency can be higher because light entering in a surrounding area of the photoelectric conversion unit can be led to the photoelectric conversion unit.

Also, the refracting unit is composed of a plurality of higher refractive index portions and lower refractive index portions that are alternately arranged in a direction away from the transmitting unit. With the above-stated construction, the refracting unit can be formed with a high degree of accuracy, and the refracting unit can also be downsized. Moreover, an effective refractive index of the refracting unit is lower in an area farther from the transmitting unit. With the above-stated construction, the light-focusing efficiency can be more improved.

A manufacturing method of a solid-state image pickup device including a light focusing layer for focusing incident light on a light receiving element, comprising: a first step of forming a light transmitting layer above a semiconductor layer in which the light receiving element is formed; a second step of forming a first mask on a part of the light transmitting layer, in which the light focusing layer is to be formed; a third step of increasing a refractive index of the light transmitting layer by implanting an ion therein; a fourth step of removing the first mask; a fifth step of forming a second mask on a part of the light transmitting layer, the part including a portion in which the ion is implanted; a sixth step of etching the light transmitting layer so as to form the light focusing layer, after the second mask is formed; and a seventh step of removing the second mask, wherein the second mask is formed so that at least a portion of the light transmitting layer is exposed. With the above-stated construction, the light focusing layer of the solid-state image pickup device of the present invention can be manufactured in a small number of semiconductor processes. Therefore, a manufacturing cost of the solid-state image pickup device can be reduced, and a period of the semiconductor processes can be shortened.

Also, the light transmitting layer is composed of a low refractive index material. Moreover, the ion is phosphorous or arsenic.

A manufacturing method of a solid-state image pickup device including a light focusing layer for focusing incident light on a light receiving element, comprising: a first step of forming a light transmitting layer composed of a higher refractive index material, above a semiconductor layer in which the light receiving element is formed; a second step of forming a refractive layer composed of a lower refractive index material on the light transmitting layer; and a third step of etching the refractive layer using the light transmitting layer as an etching stopper. With the above-stated construction, the light focusing layer can be manufactured in a small number of semiconductor processes.

A camera including a solid-state image pickup-device, wherein the solid-state image pickup device comprises: a plurality of photoelectric conversion units arranged two-dimensionally; and a plurality of light focusing units that focus incident light on the plurality of photoelectric conversion units, wherein at least two photoelectric conversion units out of the plurality of photoelectric conversion units are located more closely to each other than other photoelectric conversion units, and the at least two photoelectric conversion units share one of the plurality of light focusing units. With the above-stated construction, the light-focusing efficiency can be higher and the number of pixels can be increased. Therefore, a camera, which can take a clearer digital image, can be obtained.

### BRIEF DESCRIPTION OF THE DRAWINGS

FIG. 1 is a plan view showing a schematic construction of a solid-state image pickup device of a conventional technology.

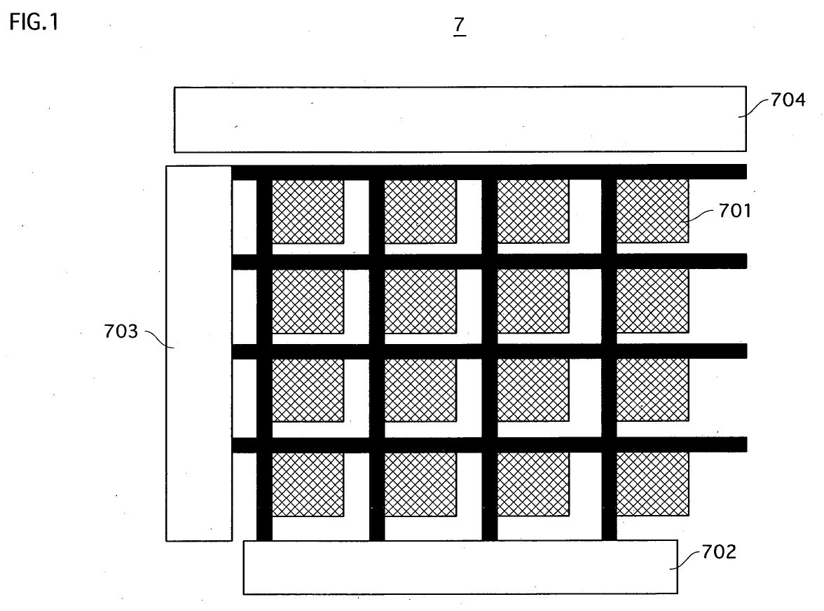

FIG. 2 is a cross section showing a part of a detailed construction of the solid-state image pickup device of the conventional technology.

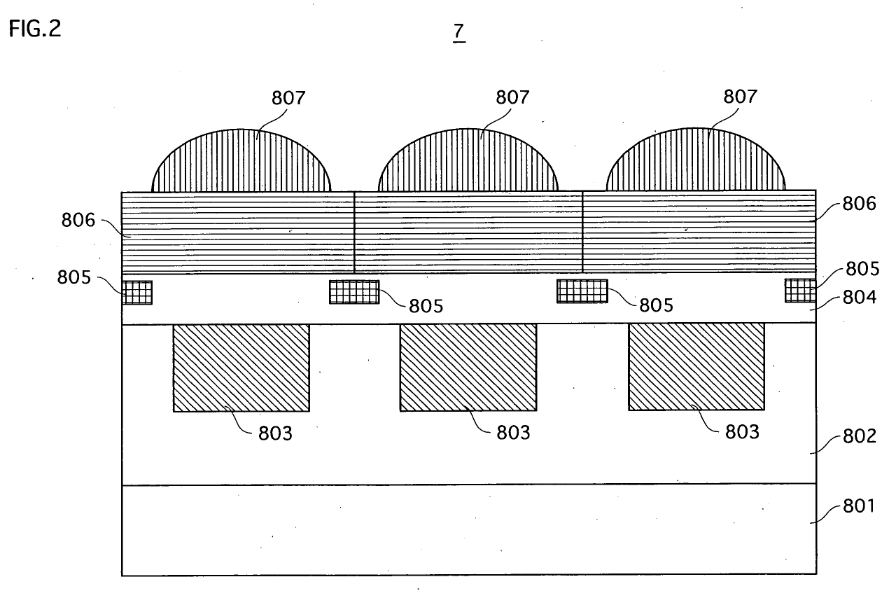

FIG. 3 is a cross section showing a part of a construction of a solid-state image pickup device of a first embodiment of the present invention.

FIG. 4 is a plan view showing a part of a construction of the solid-state image pickup device of the first embodiment of the present invention.

FIG. 5 shows a manufacturing method of the solid-state image pickup device of the first embodiment of the present invention.

FIG. 6 shows a manufacturing method of a solid-state image pickup device of a second embodiment of the present invention.

FIG. 7 is a cross section showing a part of a construction of a solid-state image pickup device of a third embodiment of the present invention.

FIG. 8 is a cross section showing a part of a construction of a solid-state image pickup device of a fourth embodiment of the present invention.

FIG. 9 shows a manufacturing method of the solid-state image pickup device of the fourth embodiment of the present invention.

FIG. 10 shows a manufacturing method of a solid-state image pickup device of a modification of the fourth embodiment of the present invention.

FIG. 11 is a block diagram showing a function construction of a digital still camera of a modification (4) of the present invention.

### DESCRIPTION OF REFERENCE NUMERALS

1, 4, 5, 6, 7: solid-state image pickup device
101, 401, 501, 601, 801: N-type semiconductor layer
102, 402, 502, 602, 802: P-type semiconductor layer
103, 403, 503, 603, 803: photodiode
104, 404, 504, 604, 804: insulating layer
105, 405, 505, 605, 805: light shielding film
106, 406, 506, 606, 806: color filter
107, 507, 607: light transmitting layer
108, 508, 608: light focusing layer
301, 302, 408, 701, 801, 802: resist mask
407: silicon dioxide layer
701: light receiving-element
702: horizontal shift register
703: vertical shift register
704: drive circuit
807: microlens
9: digital still camera
900: diaphragm mechanism
901: optical lens
902: IR cut filter
903: image sensor
904: analog signal processing circuit
905: A/D converter
906: digital signal processing circuit
907: memory card
908: control circuit

### BEST MODE FOR CARRYING OUT THE INVENTION

The following describes a solid-state image pickup device according to embodiments of the present invention, with reference to the attached drawings.

### First Embodiment

In a solid-state image pickup device of a first embodiment of the present invention, photodiodes that are closely arranged to each other share a same light focusing unit.

### (1) Construction of the Solid-State Image Pickup Device

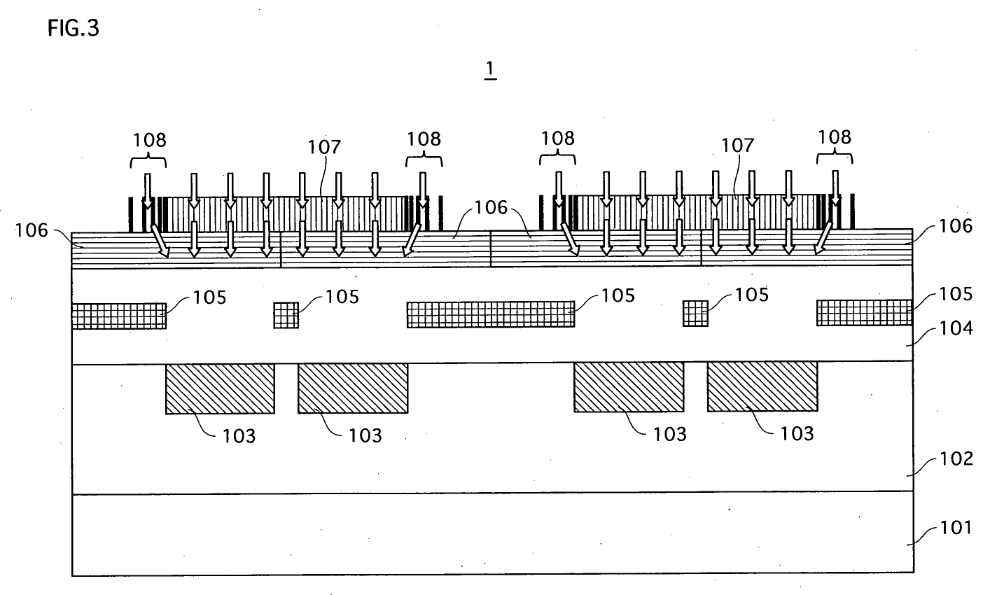

FIG. 3 is a cross section showing a part of a construction of the solid-state image pickup device of the first embodiment. As shown in FIG. 3, a solid-state image pickup device 1 includes an N-type semiconductor layer 101, a P-type semiconductor layer 102, a photodiode 103, an insulating layer 104, a light shielding film 105, color filters 106, a light transmitting layer 107, and a light focusing layer 108.

The P-type semiconductor layer 102 is formed on the N-type semiconductor layer 101. A plurality of photodiodes 103 are formed in the P-type semiconductor layer 102 on the insulating layer 104 side. The insulating layer 104 is formed on the P-type semiconductor layer 102 and the plurality of photodiodes 103. The light shielding film 105 is formed in the insulating layer 104.

The light shielding film 105 shields light transmitted through a color filter 106 to prevent the light from entering into a photodiode 103 that does not correspond to the color filter 106. Therefore, the light shielding film 105 is formed in the P-type semiconductor layer 102 at positions which do not correspond to photodiodes 103.

Each color filter 106 transmits light having a wavelength to be entered into the corresponding photodiode 103. For example, the arrangement of the color filters 106 conforms to the Bayer arrangement, according to a color of light to be transmitted. The light transmitting layer 107 is composed of titanium dioxide (TiO₂). Titanium dioxide is a dielectric material having a high translucency and a high refractive index with regard to visible light. The light transmitting layer 107 slows down a speed of incident light.

The light focusing layer 108 is composed of several fold dielectric layers so as to surround the light transmitting layer 107.

### (2) Construction of the Light Focusing Layer 108

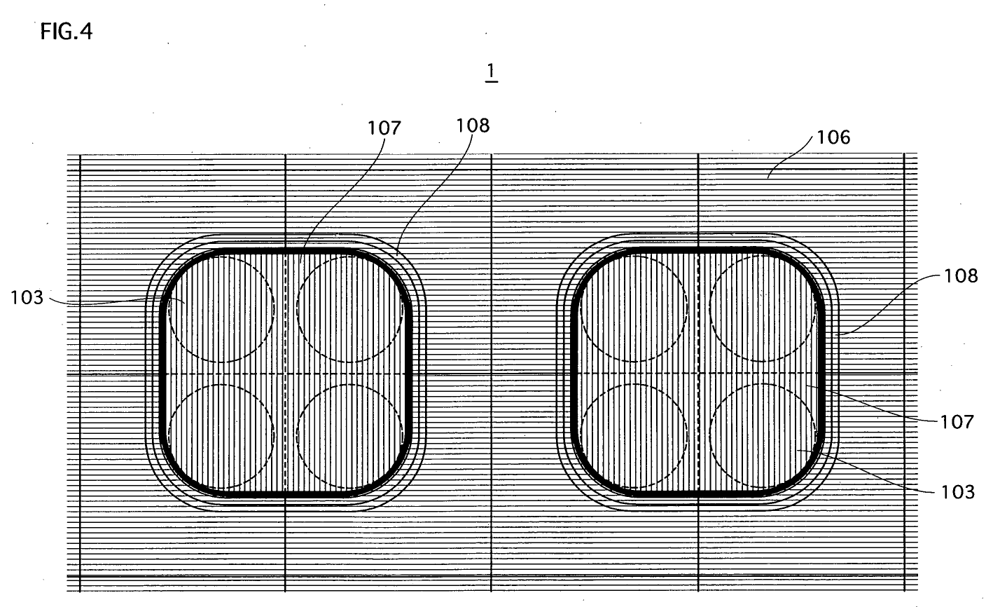

FIG. 4 is a plan view showing a construction of the solid-state image pickup device 1. As shown in FIG. 4, the light transmitting layer 107 covers photodiodes 103, and the light focusing layer 108 is formed around the light transmitting layer 107. The light focusing layer 108 includes a plurality of circular dielectric layers composed of silicon dioxide (SiO₂). Silicon dioxide has a high translucency with regard to visible light. Silicon dioxide has a refractive index that is lower than titanium dioxide, and higher than air.

An interval between dielectric layers increases as a distance from the light transmitting layer 107 increases. Also, each dielectric layer has a high refractive index, and air between dielectric layers has a low refractive index. Thus, an effective refractive index of the light focusing layer 108 is higher in an area closer to the light transmitting layer 107, and lower in an area farther from the light transmitting layer 107. The effective refractive index of the light focusing layer 108 is lower than a refractive index of the light transmitting layer 107.

Moreover, a wavelength of light to be entered is different depending on a photodiode. Thus, even if dielectric layers surround the same light transmitting layer 107, an interval between dielectric layers is different depending on which photodiode is located nearby, according to a wavelength of light which is to be entered into that photodiode.

Thus, the light focusing layer 108 refracts light entering into a surrounding area of the light transmitting layer 107 to lead the light to the light transmitting layer 107, so that the light is entered into the corresponding photodiode 103. As a result, the light-focusing efficiency can be improved.

### (3) Manufacturing Method of the Solid-State Image Pickup Device 1

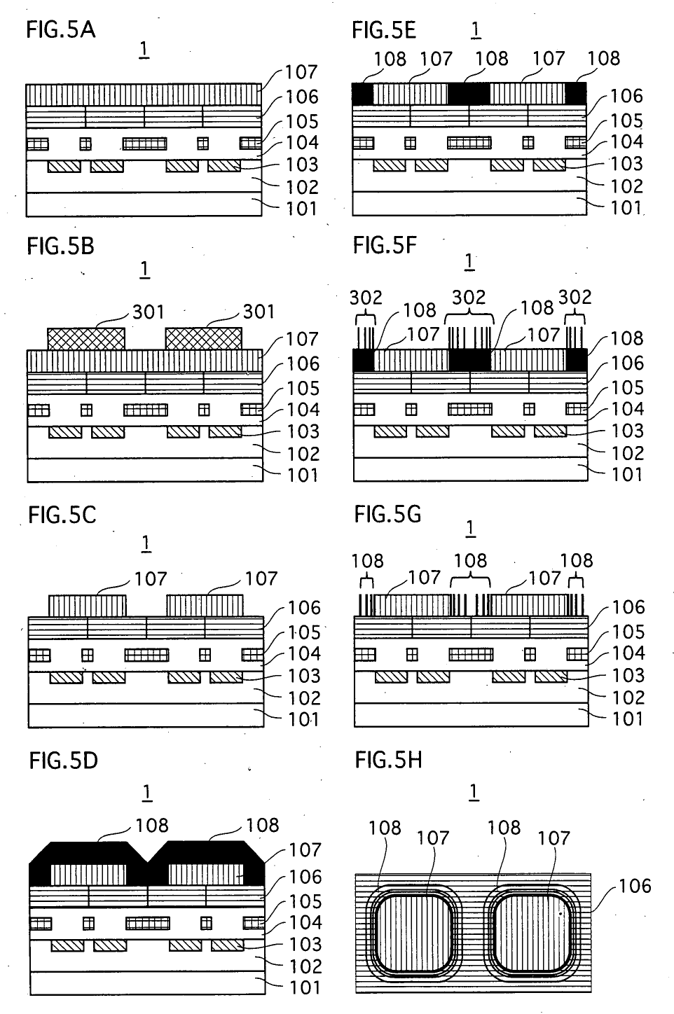

Next, a manufacturing method of the solid-state image pickup device 1 will be described. FIG. 5 shows the manufacturing method of the solid-state image pickup device 1. The N-type semiconductor layer 101, the P-type semiconductor layer 102, the photodiode 103, the insulating layer 104, the light shielding film 105, and the color filter 106 are formed. Here, the manufacturing method thereafter will be described. Firstly, the light transmitting layer 107 is formed on the color filter 106, using a sputter method or a CVD (Chemical Vapor Deposition) method as shown in FIG. 5A. Next, a resist mask 301 is formed on the light transmitting layer 107 as shown in FIG. 5B. Then, the light transmitting layer 107 is shaped by a photolithography process and a dry etching process (FIG. 5C).

As shown in FIG. 5D, the light focusing layer 108 is formed on the color filter 106 and the light transmitting layer 107, using the sputter method or the CVD method. Then, the light focusing layer 108 is planarized by a CMP (Chemical Mechanical Polishing) process (FIG. 5E). Next, a resist mask 302 is formed on the light focusing layer 108 (FIG. 5F), and the light focusing layer 108 is shaped by the photolithography process and the dry etching process (FIG. 5G). For example, carbon tetrafluoride (CF4) is used for the dry etching process. This enables the light entering into the light focusing layer 108, which surrounds the light transmitting layer 107, to be led to the photodiode 103 (FIG. 5H).

### Second Embodiment

Next, a solid-state image pickup device of a second embodiment of the present invention will be described. The solid-state image pickup device of the second embodiment has a similar construction to the solid-state image pickup device of the first embodiment, but differs in a material of a light transmitting layer. This difference will be mainly described below.

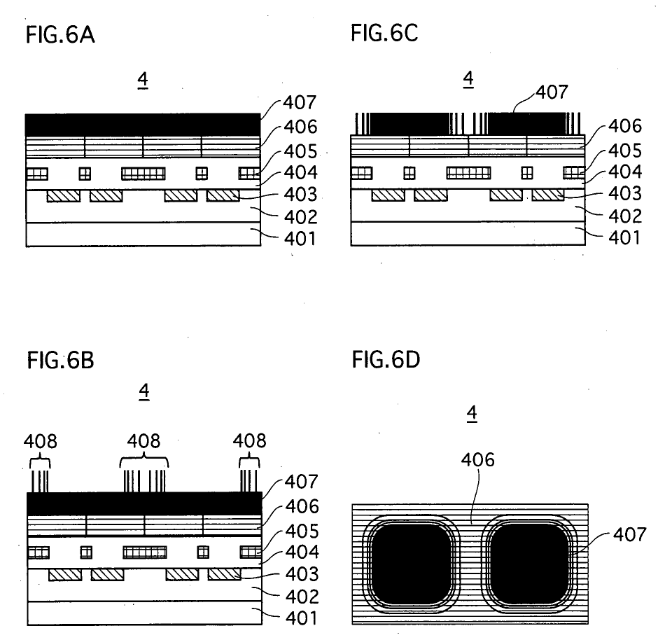

FIG. 6 shows a manufacturing method of the solid-state image pickup-device of the second embodiment. As shown in FIG. 6, a solid-state image pickup device 4 includes an N-type semiconductor layer 401, a P-type semiconductor layer 402, a photodiode 403, an insulating layer 404, a light shielding film 405, and a color filter 406. Firstly, a silicon dioxide layer 407 is formed on the color filter 406, using the sputter method or the CVD method as shown in FIG. 6A. Next, a resist mask 408 is formed on the silicon dioxide layer 407 as shown in FIG. 6B. Then, the silicon dioxide layer 407 is shaped by the photolithography process and the dry etching process (FIG. 6C). With this construction, the silicon dioxide layer 407, which has an equivalent function to the light transmitting layer 107 and the light focusing layer 108 in the first embodiment, can be manufactured in a small number of semiconductor processes.

### Third Embodiment

Next, a solid-state image pickup device of a third embodiment of the present invention will be described. The solid-state image pickup device of the third embodiment has a similar construction to the solid-state image pickup device of the first embodiment, but differs in a form of a light focusing layer. This difference will be mainly described below.

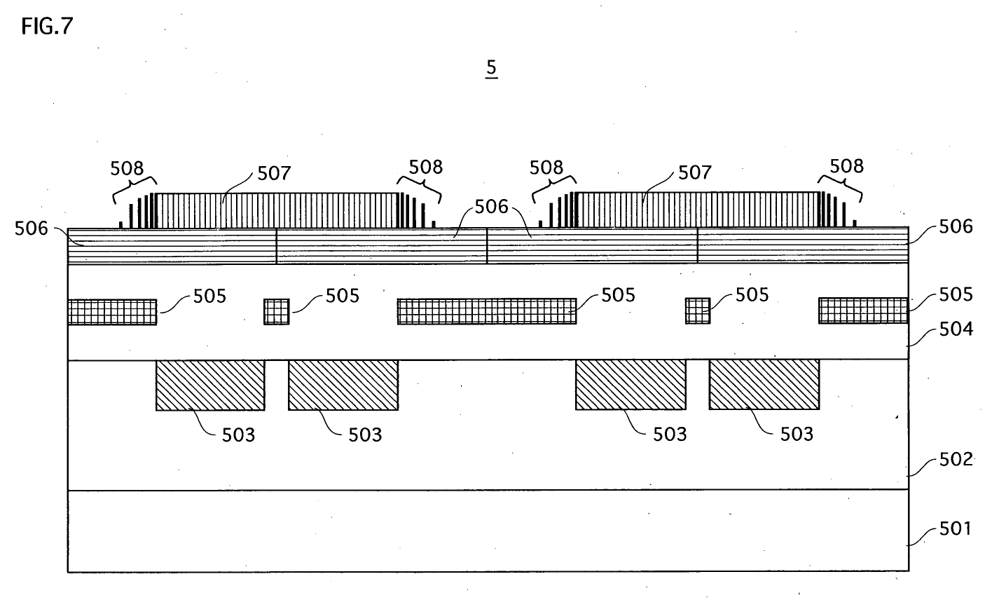

FIG. 7 is a cross section showing a part of a construction of the solid-state image pickup device of the third embodiment. As shown in FIG. 7, a solid-state image pickup device 5 includes an N-type semiconductor layer 501, a P-type semiconductor layer 502, a photodiode 503, an insulating layer 504, a light shielding film 505, a color filter 506, a light transmitting layer 507, and a light focusing layer 508.

The light focusing layer 508 includes a plurality of circular dielectric layers composed of silicon dioxide which is same as the light focusing layer 108 in the first embodiment, so as to surround the light transmitting layer 507. Each circular dielectric layer of the light focusing layer 108 in the first embodiment has a same film thickness. However, a film thickness of each circular dielectric layer of the light focusing layer 508 decreases as a distance from the light transmitting layer 507 increases.

With this construction, an effective refractive index of the light focusing layer 508 is lower in an area farther from the light transmitting layer 507. As a result, the light-focusing efficiency of the solid-state image pickup device can be higher because a refractive index effect of the light focusing layer 508 can be improved.

### Fourth Embodiment

Next, a solid-state image pickup device of a fourth embodiment of the present invention will be described. The solid-state image pickup device of the fourth embodiment has a similar construction to the solid-state image pickup device of the first embodiment, but differs in a form of a light focusing layer. This difference will be mainly described below.

### (1) Construction of the Solid-State Image Pickup Device

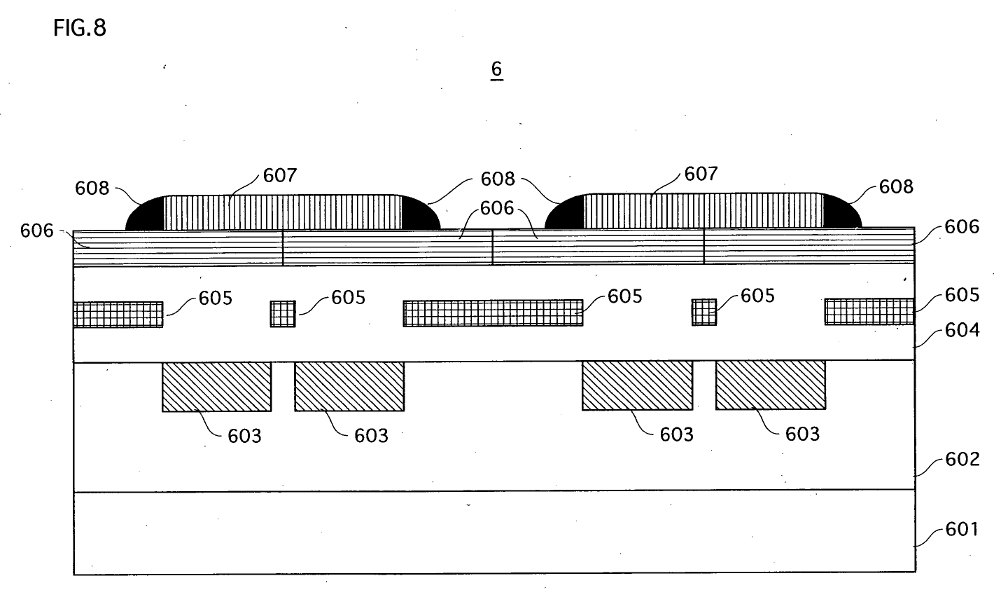

FIG. 8 is a cross section showing a part of a construction of the solid-state image pickup device of the fourth embodiment. As shown in FIG. 8, a solid-state image pickup device 6 includes an N-type semiconductor layer 601, a P-type semiconductor layer 602, a photodiode 603, an insulating layer 604, a light shielding film 605, a color filter 606, a light transmitting layer 607, and a light focusing layer 608.

The light focusing layer 608 is composed of a circular dielectric layer surrounding the light transmitting layer. 607. Also, a film thickness of the light focusing layer 608 gradually decreases as a distance from the light transmitting layer 607 increases.

With this construction, a plurality of light receiving elements share the light transmitting layer and the light focusing layer. Therefore, high light-focusing efficiency can be realized even if light receiving elements are densely mounted.

### (2) Manufacturing Method of the Solid-State Image Pickup Device 6

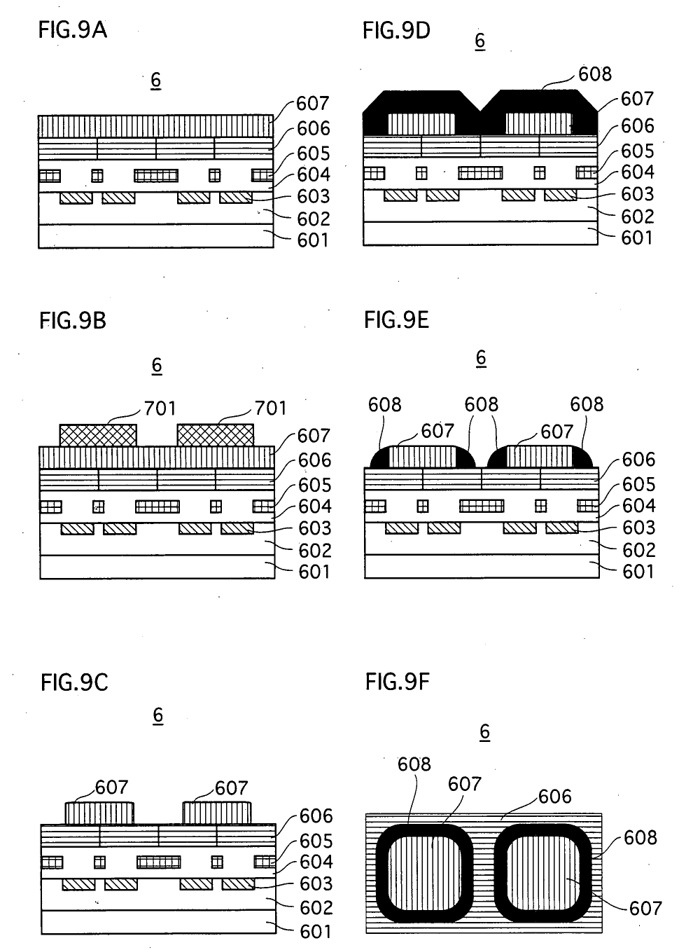

Next, a manufacturing method of the solid-state image pickup device 6 will be described. FIG. 9 shows the manufacturing method of the solid-state image pickup device 6. The N-type semiconductor layer 601, the P-type semiconductor layer 602, the photodiode 603, the insulating layer 604, the light shielding film 605, and the color filter 606 are formed. Here, the manufacturing method thereafter will be described. Firstly, the light transmitting layer 607 is formed on the color filter 606 (FIG. 9A), and a resist mask 701 is formed on the light transmitting layer 607 (FIG. 9B). Then, the light transmitting layer 607 is shaped by the photolithography process and the dry etching process (FIG. 9C).

Next, the light focusing layer 608 is formed on the color filter 606 and the light transmitting layer 607 (FIG. 9D), and the light focusing layer 608 is selectively removed by a planarizing process such as the CMP process and the like. Note that the light transmitting layer 607 is composed of titanium dioxide, and the light focusing layer 608 can be selectively removed using the light transmitting layer 607 as an etching stopper. Therefore, the forming process of the light focusing layer 608 can be stabilized. As mentioned above, the light transmitting layer 607 and the light focusing layer 608 each having a light-focusing function can be obtained (FIG. 9E). FIG. 9F is a plan view showing a part of the solid-state image pickup device 6.

### (3) Modification of the Fourth Embodiment

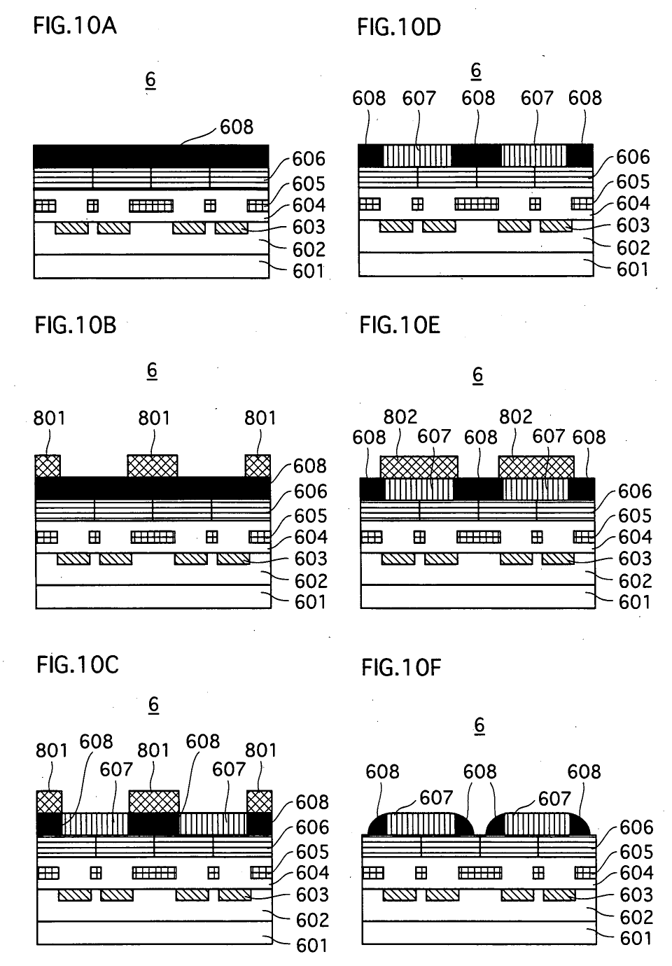

The following is a modification of the manufacturing method of the solid-state image pickup device 6. FIG. 10 shows the manufacturing method of the solid-state image pickup device 6 of the modification. The N-type semiconductor layer 601, the P-type semiconductor layer 602, the photodiode 603, the insulating layer 604, the light shielding film 605, and the color filter 606 are formed. Here, the manufacturing method thereafter will be described. Firstly, the light focusing layer 608 is formed on the color filter 606 (FIG. 10A), and a resist mask 801 is formed on the light focusing layer 608 (FIG. 10B). The light focusing layer 608 is composed of a material having a low refractive index such as silicon dioxide and the like.

Then, the light transmitting layer 607 is formed by an ion implantation method (FIG. 10C). As an ion used for the ion implantation method, a material used in a normal silicon process such as phosphorous (P), arsenic (As), and the like can be used.

After the resist mask 801 is removed (FIG. 10D), a resist mask 802 is formed on the light transmitting layer 607 (FIG. 10E). Then, the light focusing layer 608 is selectively removed by the photolithography process and the dry etching process. With this construction, a semiconductor process for obtaining the light transmitting layer 607 and the light focusing layer 608 each having a light-focusing function can be simplified and stabilized. Also, a manufacturing cost can be reduced (FIG. 10F).

### Modification

Up to now, the solid-state image pickup device of the present invention has been described specifically through the embodiments. However, the technical scope of the present invention is not limited to the above-described embodiments. For example, the following are modifications.

(1) Although it is not mentioned in the above-described embodiments, the light transmitting layer may cover a plurality of light receiving elements, or the light transmitting layer together with the light focusing layer may cover the plurality of light receiving elements. In any case, an effect of the present invention is same. Also, a form of the light transmitting layer is not limited to the form mentioned in the above-described embodiments, and a proper, form on the basis of the arrangement of light receiving elements, such as a rectangular solid form, cylinder solid form, and the like may be used.
(2) In the above-described embodiments, the light transmitting layer is formed on a gap between light receiving elements which share the light transmitting layer. However, the present invention is not limited to the construction, and may have a construction in which incident light entering into such position is entered into a nearest light receiving element by refracting the incident light. With this construction, incident light which enters into the light shielding film and does not contribute to light-focusing efficiency can be led to the light receiving element. Therefore, light-focusing efficiency can be further improved. Note that because a gap between light receiving elements is narrow, it is suitable to adjust a refractive index by forming a plurality of dielectric layers such as the light focusing layer 108 in the first embodiment.
(3) Although it is not mentioned in the above-described embodiments, a refractive index of a material generally differs according to a wavelength of transmitted light. Also, a wavelength of light to be entered differs according to a light receiving element. Therefore, it is appropriate to adjust a refractive index of a light focusing layer according to the wavelength of the light to be entered. In the first embodiment, the effective refractive index of the light focusing layer can be adjusted by adjusting the interval between dielectric layers composing the light focusing layer. In the fourth embodiment, the refractive index can be adjusted by adjusting the ion content implanted by the ion implantation method. With this construction, a higher image quality can be obtained by adjusting light-focusing efficiency according to colors.
(4) In the above-described embodiments, only the solid-state image pickup device of the present invention is described. However, the present invention is not limited to this, and an effect of the present invention may be obtained by applying the present invention to a digital still camera (DSC).

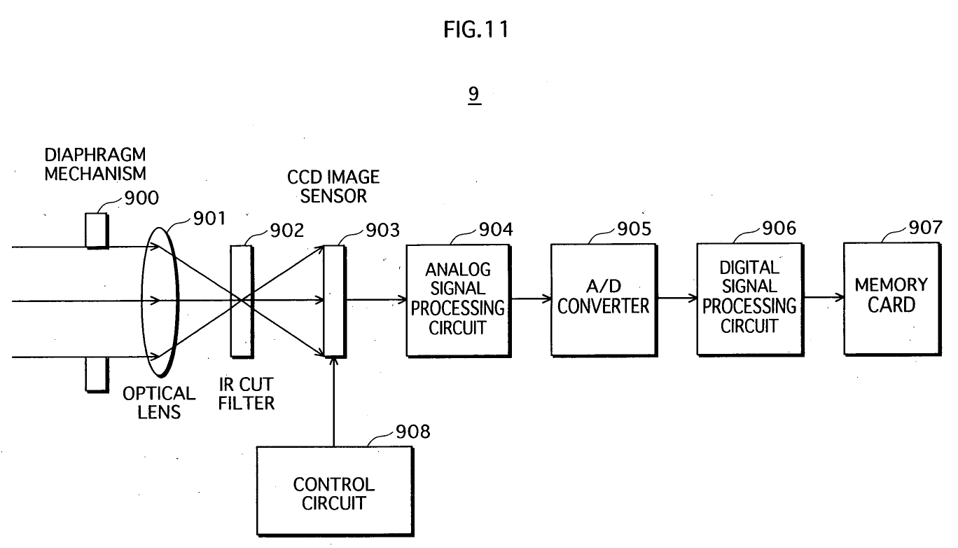

FIG. 11 is a block diagram showing a function construction of a digital still camera of the modification. As shown in FIG. 11, a digital still camera 9 includes a diaphragm mechanism 900, an optical lens 901, an IR (Infrared Rays) cut filter 902, an image sensor 903, an analog signal processing circuit 904, an A/D (Analog to Digital) converter 905, a digital signal processing circuit 906, a memory card 907, and a control circuit 908.

The diaphragm mechanism 900 adjusts an amount of light entering into the optical lens 901. The diaphragm mechanism 900 includes two diaphragm blades. When the two diaphragm blades are separated from each other, an amount of light entering into the image sensor 903 increases because an amount of light entering into the optical lens 901 increases. On the other hand, when the two diaphragm blades are close to each other, an amount of light entering into the image sensor 903 decreases.

The optical lens 901 focuses incident light from an object on the image sensor 903. The IR cut filter 902 removes a long-wavelength component of light entering into the image sensor 903. The image sensor 903 is a single-plate CCD (Charge Coupled Device) image sensor, in which a color filter for filtering incident light is provided for each of light receiving elements arranged two-dimensionally. The arrangement of color-filters conforms to the Bayer arrangement, for example. The image sensor 903 reads a charge according to a drive signal from the control circuit 908, and outputs an analog image signal.

Note that the light receiving elements included in the image sensor 903 are unequally arranged two-dimensionally. In other words, at least two light receiving elements out of the light receiving elements included in the image sensor 903 are arranged more closely to each other than other light receiving elements. This can realize a high resolution. As described in the first embodiment and the like, the light receiving elements closely arranged to each other share a light transmitting layer and a light focusing layer.

The analog signal processing circuit 904 performs processes such as correlated double sampling, signal amplification, and the like on the analog image signal outputted from the image sensor 903. The A/D converter 905 converts the output signal from the analog signal processing circuit 904 into a digital image signal. The digital signal processing circuit 906 corrects a color shift of the digital image signal so as to generate a digital picture signal. The memory card 907 records the digital picture signal. The recorded digital picture signal is a digital photo.

### INDUSTRIAL APPLICABILITY

The solid-state image pickup device of the present invention is useful as a technology for improving the light-focusing efficiency of a solid-state image pickup device in which a plurality of light receiving elements are densely mounted.

1. A solid-state image pickup device, comprising:
a plurality of photoelectric conversion units arranged two-dimensionally; and
a plurality of light focusing units that focus incident light on the plurality of photoelectric conversion units, wherein
at least two photoelectric conversion units out of the plurality of photoelectric conversion units are located more closely to each other than other photoelectric conversion units, and
the at least two photoelectric conversion units share one of the plurality of light focusing units.

2. The solid-state image pickup device of claim 1, wherein
each of the plurality of light focusing units includes:
a transmitting unit that transmits light entering therein; and
a refracting unit that surrounds the transmitting unit, and refracts incident light toward each of the plurality of photoelectric conversion units.

3. The solid-state image pickup device of claim 2, wherein
a refractive index of the transmitting unit is larger than a refractive index of the refracting unit.

4. The solid-state image pickup device of claim 2, wherein
a refractive index of the refracting unit is lower in an area farther from the transmitting unit.

5. The solid-state image pickup device of claim 2, wherein
the refracting unit is composed of a plurality of higher refractive index portions and lower refractive index portions that are alternately arranged in a direction away from the transmitting unit.

6. The solid-state image pickup device of claim 2, wherein
an effective refractive index of the refracting unit is lower in an area farther from the transmitting unit.

7. A manufacturing method of a solid-state image pickup device including a light focusing layer for focusing incident light on a light receiving element, comprising:
a first step of forming a light transmitting layer above a semiconductor layer in which the light receiving element is formed;
a second step of forming a first mask on a part of the light transmitting layer, in which the light focusing layer is to be formed;
a third step of increasing a refractive index of the light transmitting layer by implanting an ion therein;
a fourth step of removing the first mask;
a fifth step of forming a second mask on a part of the light transmitting layer, the part including a portion in which the ion is implanted;
a sixth step of etching the light transmitting layer so as to form the light focusing layer, after the second mask is formed; and
a seventh step of removing the second mask, wherein the second mask is formed so that at least a portion of the light transmitting layer is exposed.

8. The manufacturing method of claim 7, wherein
the light transmitting layer is composed of a low refractive index material.

9. The manufacturing method of claim 7, wherein
the ion is phosphorous or arsenic.

10. A manufacturing method of a solid-state image pickup device including a light focusing layer for focusing incident light on a light receiving element, comprising:
a first step of forming a light transmitting layer composed of a higher refractive index material, above a semiconductor layer in which the light receiving element is formed;
a second step of forming a refractive layer composed of a lower refractive index material on the light transmitting layer; and
a third step of etching the refractive layer using the light transmitting layer as an etching stopper.

11. A camera including a solid-state image pickup device, wherein
the solid-state image pickup device comprises:
a plurality of photoelectric conversion units arranged two-dimensionally; and
a plurality of light focusing units that focus incident light on the plurality of photoelectric conversion units, wherein
at least two photoelectric conversion units out of the plurality of photoelectric conversion units are located more closely to each other than other photoelectric conversion units, and
the at least two photoelectric conversion units share one of the plurality of light focusing units.
